(19) United States
(12) Patent Application Publication
(10) Pub. No.: US 2005/0138535 A1
(43) Pub. Date: Jun. 23, 2005

(54) Method and system for branch metric calculation in a viterbi decoder

(76) Inventors: Sivagnanam Parthasarathy, Carlsbad, CA (US); Alessandro Risso, San Diego, CA (US)

Correspondence Address: STMICROELECTRONICS, INC, MAIL STATION 2346, 1310 ELECTRONICS DRIVE, CARROLLTON, TX, 75006, US

(21) Appl. No.: 10/727,063

(22) Filed: Dec. 2, 2003

(51) Int. Cl. G06K 5/04; G11B 5/00; G11B 20/20; H03M 13/03

(52) U.S. Cl. 714/796

(57) ABSTRACT

In a convolutional decoder, eight branch labels for branches in two trellis butterflies are calculated using a single output of an encoder. For a group of four consecutive states, Sᵢ, Sᵢ₊₁, Sᵢ₊₂, and Sᵢ₊₃, state Sᵢ₊₃ is loaded into a convolutional encoder and the convolutional encoder input bit is set to 1. The output bits of the convolutional encoder are used as a branch label in a first trellis butterfly. A branch label in the second trellis butterfly is calculated with a formula in a branch label calculator using the convolutional encoder output bits as an input to the formula. The remaining branch labels are calculated from the convolutional encoder output and the branch label output from the branch label calculator. Selected bits of the branch labels are used to address a small branch metric register file.

### BACKGROUND OF THE INVENTION

1. Field of the Invention

The present invention relates generally to a Viterbi decoder and a Viterbi decoding method used in a maximum likelihood decoding method of a convolutional code used in a digital data communication system.

2. Description of the Prior Art

The need for reliable data transfer is becoming more and more important in today's digital world. When transferring data bits over a channel, the Viterbi algorithm is widely used for reducing the effects of noise that may corrupt a data stream. The Viterbi algorithm belongs to a large class of error correcting codes known as convolution codes.

An example of a simple convolutional encoder 20 is depicted in FIG. 1. The rate of a convolution coder is defined as the ratio of the number of input bits to the number of output bits. Convolutional encoder 20 has a rate of ½ because the system encodes 1 input information bit 22 to produce 2 output encoded bits 24. Convolutional encoder 20 has a shift register 26 for storing m-number of information bits 28 and 30, and modulo-2 adders 32 and 34 that combine selected input bits to produce an output bit.

The number of bits that can be connected to a modulo-2 adder to influence the encoding of one output bit is called the “constraint length.” In this document the constraint length is represented by the variable “K.” Encoder 20 has a constraint length K=3 because 3 bits-22, 28, and 30—are used to compute output bits 24. The selected connections between information bits 22, 28, and 30 and modulo-2 adders 32 and 34 may be described by equations called “generator polynomials.” A set of generator polynomials are represented herein as G[p:0][K-1:0], where (p-1)-number of polynomials G are used, and each polynomial includes (K-2) bits (because it is assumed that the input bit is always connected to a modulo-2 adder). In the example of FIG. 1, there are 2 generator polynomials used; the first generator polynomial, which produces the first output bit (the output of modulo-2 adder 34), is G₀[1,1,1], and the second generator polynomial for the second output bit (the output of modulo-2 adder 32) is G₁[1,0,1], where a 1 indicates a connection from a respective input bit memory location to a modulo-2 adder.

FIG. 2 shows part of a more complex convolutional encoder 40 that can be selectively configured for various coding rates, and for non-recursive or recursive encoding. Encoder 40 encodes one output bit V₁ 42 for every input bit 43 according to generator polynomial Gᵢ[7:0] 44. The generator polynomial 44 describes the connections between state bits S7 through S0 in shift register 46 and modulo-2 adders 48. For a rate 1/N encoder, N-1 additional generator polynomials 44 and modulo-2 adder 48 circuits are added in parallel to produce N outputs, V[N-1:0], where each output bit is generated from input bit 43 and selected state bits S7 through S0 selected by one of p-1 generator polynomials G[p:0][K-2:0]. Note that p and N are not necessarily equal, and if N>p, then some generator polynomials 44 may be used more than once to produce more than one output bit 42.

If convolutional encoder 40 is configured to operate in a recursive encoding mode, bit REC 50 is set to 1 and feedback polynomial GF[K-2:0] 52 is specified to determine connections between shift register 46 and modulo-2 adders 54.

By selecting the proper generator polynomials, encoder 40 can be configured for constraint lengths K from 4 to 9 (i.e., 4<=K<=9). For example, for K=7, Gᵢ[7] and Gᵢ[6] are set to 0 in each generator polynomial. In a preferred embodiment of encoder 40, N sets of generator polynomials 44 and modulo-2 adders 48 may be used in parallel to produce various 1/N code rates, such as ½ to ⅙ (i.e., 2<=N<=6).

At the receiver of a digital data message, a Viterbi decoder may be used to decode the encoded stream of information bits by finding the maximum likelihood estimate of the transmitted sequence. Viterbi decoders are commonly used to decode the convolutional codes used in wireless applications. And other applications of forward error correcting codes and Viterbi decoders include CD and DVD players, high-definition TV, data-storage systems, satellite communications, and modem technologies.

The trellis diagram depicted in FIG. 4 is useful for diagramming the decoding process over time. It can be seen as a flow-control diagram where each node represents an encoder state, and the transitions from one state to another happen depending on the data input stream. Each of the 2^{K-1} nodes in a column of the trellis diagram denotes one of the potential 2^{K-1} encoder states. From any node a transition can be made—along a “branch” or “edge”—to one of two other nodes, depending upon whether a 0 or a 1 was received as an input data bit. Each branch has an associated “branch label” or “branch word” that is the output from the encoder that results from the transition of one encoder state to another in response to the 0 or 1 input bit.

The Viterbi algorithm is comprised of two routines-a metric update and a traceback. The metric update accumulates distances in code space for all states based on the current input symbol using the state transitions represented by the trellis diagram (similar to FIG. 4). The traceback routine reconstructs the original data once a path through the trellis is identified.

As shown in the block diagram of Viterbi decoder 70 in FIG. 3, branch metric unit 72 and add compare select (ACS) unit 74 perform the forward computational part of the Viterbi algorithm, while trace back unit 76 reconstructs the original data. The ACS operations are typically done by working on selected pairs of states that form a butterfly structure of the trellis. The operations consist of adding the previous path metrics to the respective branch metrics, and at each next state node selecting the best value (i.e., either a maximum or a minimum depending upon the convention of the metrics used) for the new path metrics and saving the decision bit that denotes which branch was chosen. A “branch metric” is the distance between the received sequence and the branch label. This distance is either hamming (for hard-decision decoding) or Euclidean (for soft-decision decoding). An accumulation of branch metrics forms the “state metric” or “path metric.” The set of branch metrics for a stage in the trellis are derived from the received data usually at one time point. The Viterbi decoder will generate a branch metric value for each of the possible branches based on the input actually received by the decoder.

The problem of branch metric computation depends upon the generator polynomials and the state bits of the trellis butterfly for the current ACS operation. To find a branch label for one branch, the decoder hardware essentially implements the encoder function with the user supplied generator polynomials and a hypothetical input bit.

Therefore, it should be apparent that there is a need for an improved Viterbi decoder that efficiently calculates branch labels using fewer encoder cycles, less circuitry, and smaller silicon area.

### SUMMARY OF THE INVENTION

In a convolutional decoder according to an embodiment of the invention, eight branch labels for branches in two trellis butterflies are calculated using a single output of an encoder. For a group of four consecutive states, Sᵢ, Sᵢ₊₁, Sᵢ₊₂, and Sᵢ₊₃, state Sᵢ₊₃ is loaded into a convolutional encoder and the convolutional encoder input bit is set to 1. The output bits of the convolutional encoder are used as a branch label in a first trellis butterfly. A branch label in the second trellis butterfly is calculated with a formula in a branch label calculator using the convolutional encoder output bits as an input to the formula. The remaining branch labels are calculated from the convolutional encoder output and the branch label output from the branch label calculator. Selected bits of the branch labels are used to address a small branch metric register file.

For decoding a recursive code, a second formula is substituted for the formula used in a non-recursive system.

### BRIEF DESCRIPTION OF THE DRAWINGS

For a more complete understanding of the present invention, and the advantages thereof, reference is now made to the following descriptions taken in conjunction with the accompanying drawings, in which like numbers designate like parts, and in which:

FIG. 1 is a high-level schematic diagram of a prior art convolutional encoder;

FIG. 2 is a portion of a more complex prior art convolutional encoder that can be programmed to operate in various modes;

FIG. 3 is a high-level block diagram of a prior art Viterbi decoder;

FIG. 4 is a prior art trellis diagram;

FIG. 5 is a high-level block diagram of a portion of a convolutional decoder for calculating branch labels for two trellis butterflies in accordance with the method and system of the present invention;

FIG. 6 is a high-level block diagram of a portion of a convolutional decoder in accordance with the method and system of the present invention;

FIG. 7 is a block diagram of a logic circuit used for calculating a branch label in accordance with the method and system of the present invention; and

FIG. 8 is a high-level block diagram of a data receiver in accordance with the present invention.

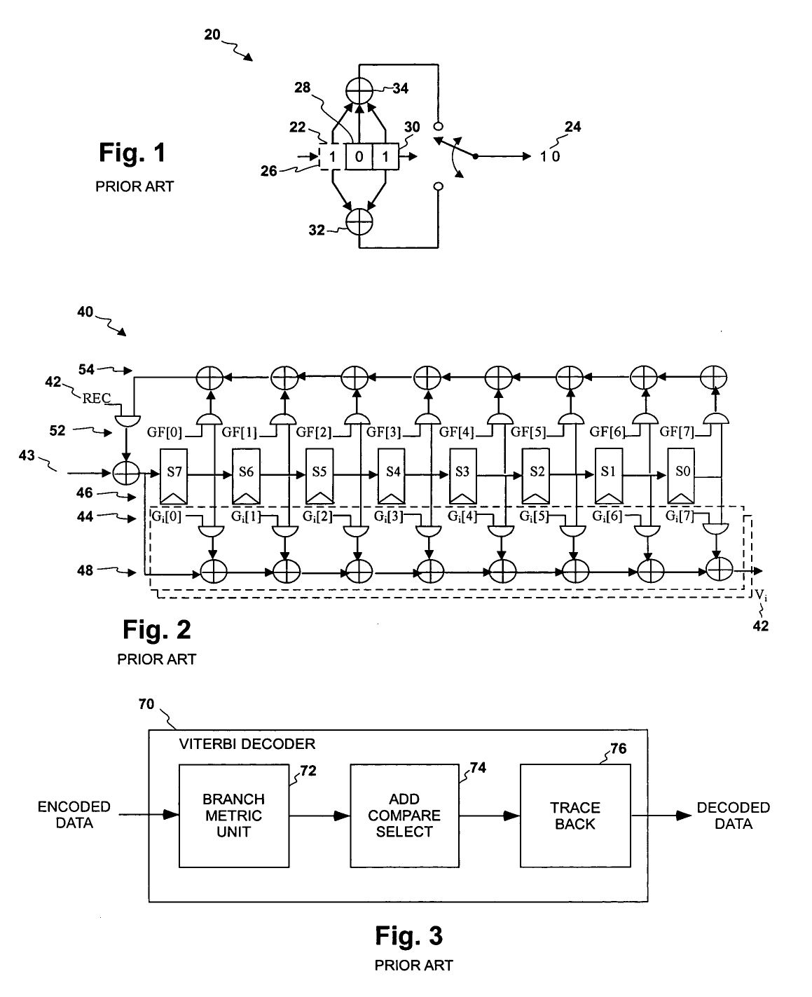

### DESCRIPTION OF THE PREFERRED EMBODIMENTS

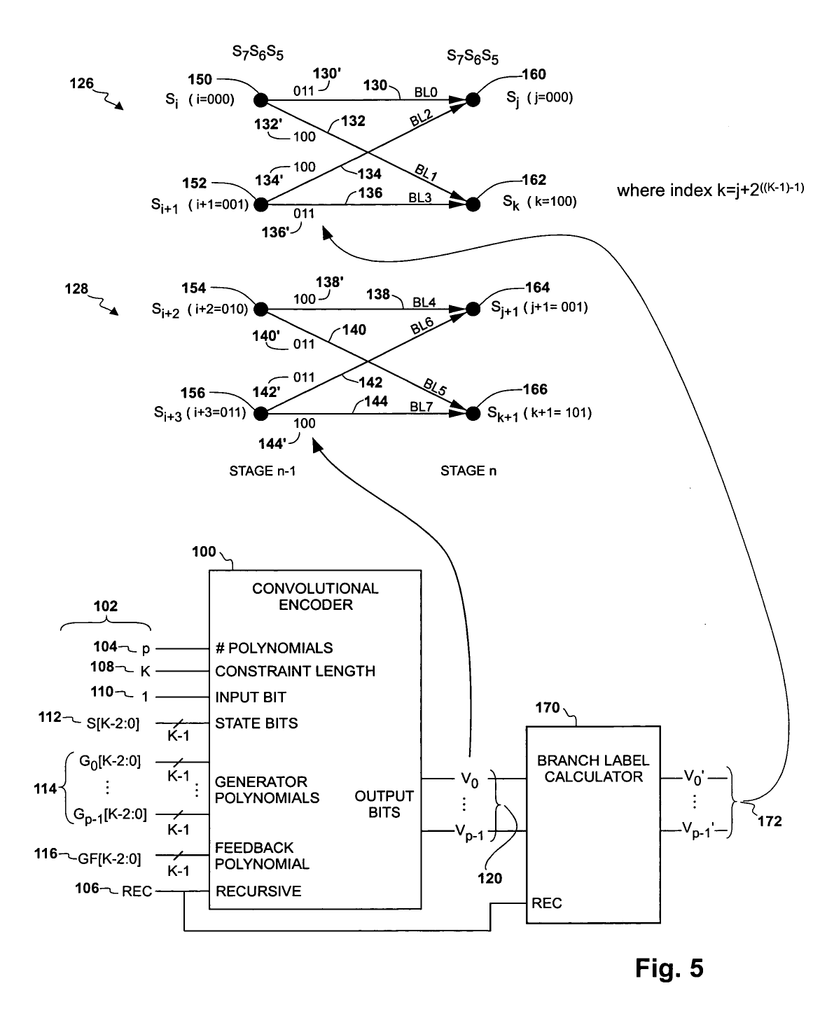

With reference now to the drawings, and in particular with reference to FIG. 5, there is depicted a high-level block diagram of a branch label calculator associated with branches in two trellis butterflies in accordance with the present invention. As shown, a configurable convolutional encoder 100 receives encoder parameters 102 to configure the encoder according to known encoding parameters used on the transmitter side of the data link. Parameters 102 may include, for example, number of generator polynomials p 104, bit REC 106 to indicate whether or not recursive encoding is used, constraint length K 108, input bit 110, K-1 number of state bits 112, p number of generator polynomials 114, and feedback polynomial 116. Encoder 100 may be implemented with encoder 40 shown in FIG. 2.

In a preferred embodiment, the number of polynomials p 104 may be limited to three distinct polynomials. Therefore, if the code rate is greater is than ⅓, some generator polynomials are repeated so that a selected polynomial is used to produce more than one output bit 120. The code rate is preferably from ½ to ⅙, inclusive. Constraint length K 108 is preferably from four to nine, inclusive. State bits 112 set the bits in the shift register, or memory locations, such as bits S0-S7 shown in shift register 46 in FIG. 2. In FIG. 2, S7 is the newest bit shifted into shift register memory 46, and S0 is the oldest bit in shift register memory 46. Generator polynomials 114 are of degree K-1 or less, and they specify the connections between the shift register 46 and the modulo-2 adder adders 48 (see FIG. 2). In FIG. 2, G[0] represents the presence or absence of a connection between S7, the newest bit in shift register memory 46, and a modulo-2 adder, and G[7] represents the presence or absence of a connection between S0, the oldest bit in shift register memory 46, and a modulo-2 adder.

In a Viterbi decoder, branch labels are calculated for every node in the decoding trellis at each unit of time. For each trellis butterfly, one label may be calculated and the remaining three labels may be easily derived.

FIG. 5 shows how output bits V₀ . . . Vₚ₋₁ 120 from convolutional encoder 100 represent a p-bit output branch word or branch label generated using the encoder state set by state bits 112 and the encoder mode set by parameters 102. Two trellis butterflies 126 and 128 are shown at the top of FIG. 5. Trellis butterfly 126 includes branches or edges 130-136, with corresponding branch labels 130′-136′. Trellis butterfly 128 includes branches or edges 138-144, with corresponding branch labels 138′-144′. Branch labels 130′-144′ are also shown generically as BL0-BL7.

As shown by the arrow pointing to lower trellis butterfly 128, output bits 120 may be used as branch label 144′ for branch 144.

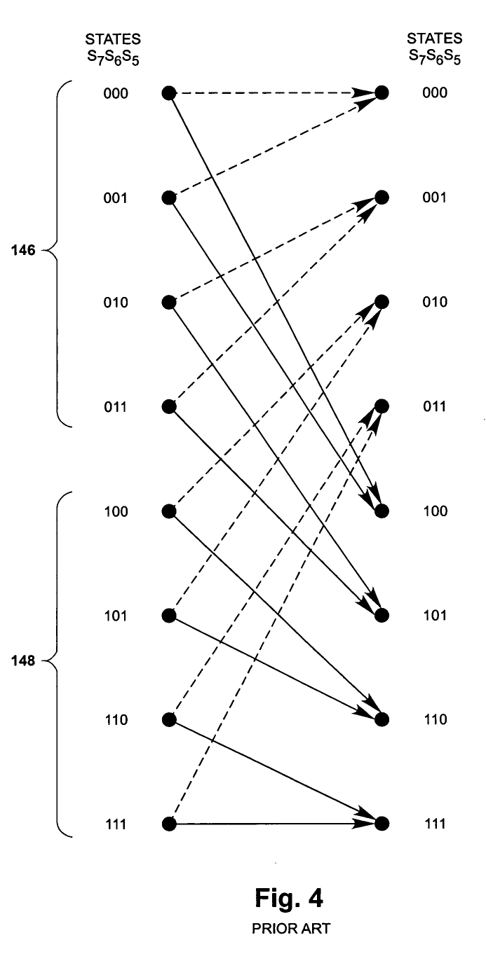

According to an important aspect of the present invention, branch is labels are calculated for a selected group of four states in a trellis diagram. As shown in FIG. 5, states 150-156 are four consecutive states in a trellis. For example, 2 groups of four consecutive states are shown at group 146 and group 148 in FIG. 4. The “next state” indexes j and k for the two butterflies 126 and 128 are related by the formula:
k=j+2^{((K-}2)−1)

The first state in the group of four, Sᵢ 150, is preferably selected by a modulo-4 counter. In order to calculate branch label 144′ associated with the fourth state Sᵢ₊₃ 156 in the group of four, convolutional encoder 100 is loaded with parameters 102, including input bit 110 equal to 1, to produce output bits 120, which are used as branch label 144′ (which is also BL7) for branch 144. The remaining branch labels 138′ through 142′ in butterfly 128 may be calculated or derived from branch label 144′. For example, branch label 138′ is the same as branch label 144′, and branch labels 140′ and 142′ are the inverse of branch label 144′.

To obtain branch labels 130′-136′ in trellis butterfly 126, output bits 120 are used as inputs to branch label calculator 170, which outputs bits 172 that are used as branch label 136′. Once branch label 136′ is known, the remaining branch labels 130′-134′ of trellis butterfly 126 may be derived or calculated as follows: branch label 130′ is the same as branch label 136′ and branch labels 132′ and 134′ are the inverse of branch label 136′.

Thus, using the symbols BL0-BL7, BL3 is related to BL7 by a function executed within branch label calculator 170. The following equations show the relationships between the branch labels of two butterfly trellises 126 and 128.
BL4=BL7
BL5=BL6=\overline{BL7}
BL3=f(BL7)
BL0=BL3
BL1=BL2=\overline{BL3}

An important advantage of the present invention is that branch labels for two butterfly trellises may be calculated using one output cycle of one convolutional encoder. This is accomplished by using combinatorial logic within branch label calculator 170 to implement a formula for a bit-wise calculation of a branch label of a second butterfly using a branch label of a first butterfly. As shown in FIG. 5, the output of convolutional encoder 100 provides branch label 144′ for the first trellis butterfly 128, while the output of branch label calculator 170 provides branch label 136′ for the second trellis butterfly 126.

The inputs to branch label calculator 170 are output bits 122 from convolutional encoder 100 and bit REC 106, which indicates whether or not convolutional encoder 100 is operating in a recursive or non-recursive mode. The outputs of branch label calculator 170 are output bits 172, which are equivalent to the output of convolutional encoder 100 if it had been set to state 152 with a 1 applied at input bit 110. These output bits may also be referred to as “the branch label for the input equals 1 transition from state Sᵢ₊₁ to state Sₖ.”

By calculating output bits 172 from bits 120, the decoder can calculate 8 branch labels in a single cycle of one convolutional encoder 100. In a typical Viterbi decoder application, a convolutional decoder 100 would be loaded with parameters 102 at least twice to produce two sets of output bits 120 in order to calculate branch labels for two butterfly trellises. By using branch label calculator 170, the number of encoder cycles can be reduced by one-half, thereby saving the space needed to provide a second parallel convolutional encoder, or alternatively reducing the time needed for two encoding cycles to calculate the two branch labels.

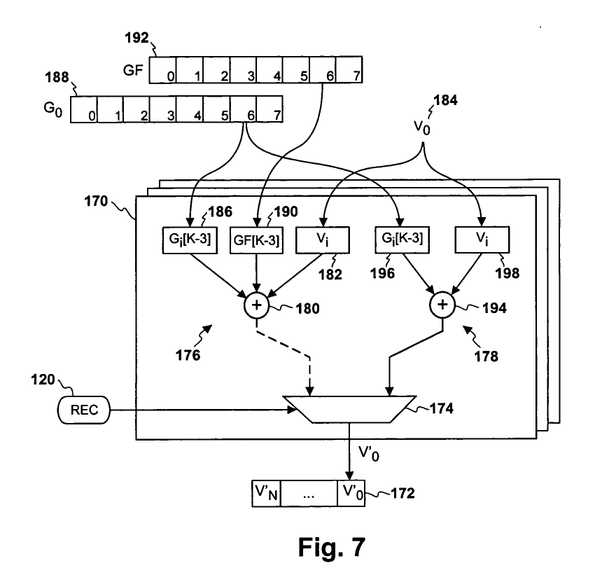

The formulas and high-level logic used to implement the formulas of branch label calculator 170 are shown in FIG. 7. As illustrated, output bits 172 are calculated by one of two formulas depending upon the state of REC bit 120, which indicates whether or not the decoder is decoding a recursive or non-recursive convolutional code. If REC bit 120 is true, indicating the decoder is in the recursive mode, formula 176 on the left branch of the multiplexer 174 is used. This formula calculates one bit Vᵢ of output bits 172 by exclusive oring three input bits. One of the three input bits to exclusive or gate 180 is output bit Vᵢ 120 from convolutional encoder 100 (See FIG. 5) that corresponds to the selected one of the N-bits of V′ being calculated. As an example, inputs for branch label calculator 170 are shown for calculating bit V′₀. Therefore, input bit Vᵢ 182 is equal to V₀ 184. Bit 186 is selected from generator polynomial G₀ 188. Bit 186 is the (K-3)-bit of generator polynomial G₀ 188, where, for this example, K=9 and the bits in generator polynomial G₀ are labeled in descending order from the right most bit of G₀.

Since the encoder is set in the recursive encoding mode, bit 190 is taken from feedback polynomial GF 192 from the (K-3) bit position, which for K=9 is the sixth bit of feedback polynomial GF 192. When REC bit 120 is true, multiplexer 174 selects the output of exclusive or gate 180 and outputs V′ᵢ, one of the bits in output bits 172.

If REC bit 120 is false, the non-recursive mode is selected, and multiplexer 174 selects the output of exclusive or gate 194, which executes the formula for calculating bit V′ᵢ for an encoder set to a non-recursive mode. Inputs to exclusive or gate 194 are the (K-3)-bit 196 of the ith generator polynomial 188. In the example shown for calculating V′₀, generator polynomial 188 is G₀. And for K=9, the sixth bit is selected, wherein the bits in G₀ 188 are numbered from zero in ascending order from the left.

Similar to formula 176, bit 198 is a selected bit Vᵢ 120 corresponding to the bit V′ᵢ being calculated. As shown in FIG. 7, output bits 172 are calculated in a bit-wise manner by inputting corresponding bit Vᵢ 120 and selecting the (K-3) bit from corresponding generator polynomials 188 and feedback polynomials 192. This bit-wise calculation is indicated by several circuits 170 stacked in parallel, where one circuit calculates each output bit V′ᵢ.

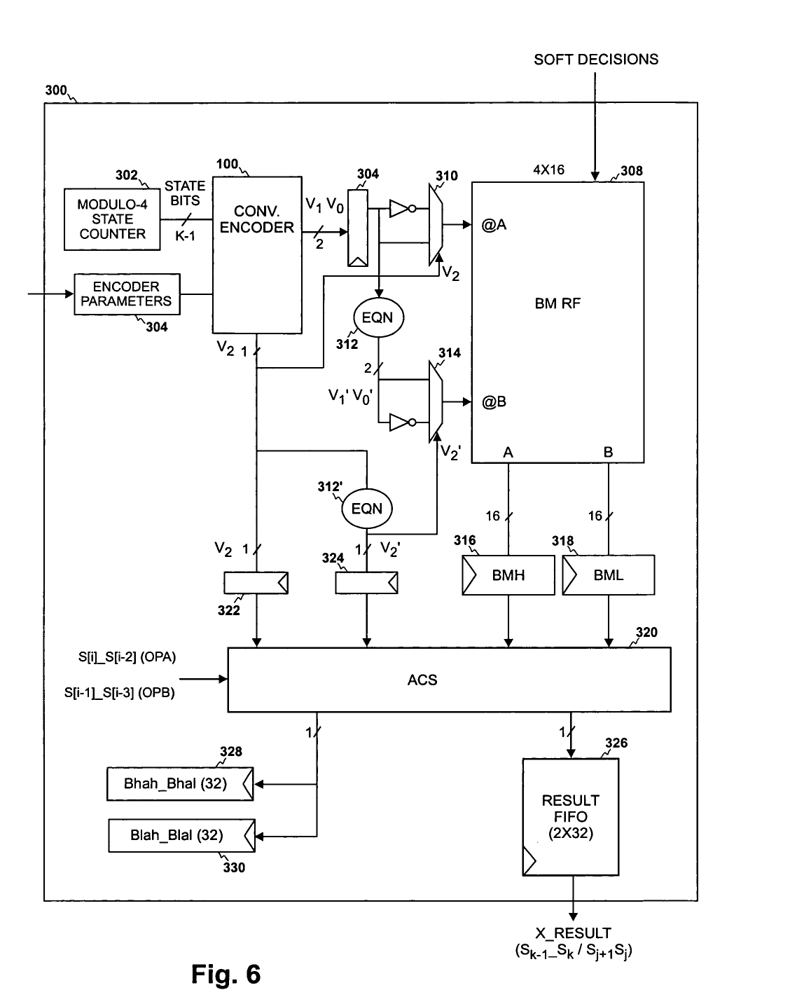

With reference now to FIG. 6, there is depicted a high-level block diagram of a, portion of a co-processor for decoding a convolutional code using the Viterbi algorithm. As illustrated, co-processor 300 includes modulo-four state counter 302 that is used to select one state of the four consecutive states used to form two trellis butterflies. An example of the four selected states appears at group 146 in FIG. 4 and at the top of FIG. 5, which shows states 150-156. The output of modulo four state counter 302 is coupled to convolutional encoder 100, which is similar to the convolutional encoder shown in FIG. 5 and FIG. 2.

Convolutional encoder 100 also receives inputs from encoder parameters 304. These encoder parameters are similar to encoder parameters 102 shown in FIG. 5. The encoder parameters may include: p, for specifying the number of polynomials; REC bit, for specifying whether or not the convolutional encoder operates in a recursive or non-recursive mode; constraint length K; an input bit; state bits; generator polynomials; and a feedback polynomial.

Convolutional encoder 100 outputs bits V₀-V₂, which represent the branch label or branch word for a particular branch or transition in the butterfly. Bits V₀-V₁, the least significant bits of the branch label, are stored in register 306. The output of register 306 is used to provide a two-bit address for branch metric register file 308. Register file 308 is a dual port memory that simultaneously receives two addresses shown as “@A” and “@B”. Multiplexer 310 selects bits V₁V₀ or the inverse of V₁V₀, depending upon the state of V₂, which selects address @A as the output of multiplexer 310.

Output bits V₁V₀ are also input into branch label calculator 312, which is the same as branch label calculator 170 shown in FIG. 7. The outputs of branch label calculator 312 are bits V₁′V₀′, which are input into multiplexer 314, along with the inverse of V₁′V₀′. The output of multiplexer 314 is provided to branch metric register file 308 as address “@B” depending upon the state of V₂′, which selects the output of multiplexer 314.

Note that through addresses @A and @B, the lower two bits (least significant two bits) of Vᵢ and Vᵢ′, and their inverses, supply all address bits needed to access the 4×16 register file 308. Register file 308 is used to store information needed to recreate 8 branch metrics for all transitions in two trellis butterflies. The branch metrics are stored as combinations of four- or eight-bit soft decisions.

The output of register file 308 is provided at outputs A and B, which are each 16 bits wide and connected to registers BMH 316 and register BML 318. BMH is the branch metric value stored at address @A and BML is the branch metric value stored at address @B. Registers 316 and 318 hold these branch metric values for use in calculations in add-compare-select unit 320. Add compare select unit 320 also receives inputs V₂ and V₂′ from registers 322 and 324, respectively. Note that V₂′ is calculated by branch label calculator 312′, which is the same as to branch label calculator 170 shown in FIGS. 5 and 7.

Add-compare-select unit 320 adds or subtracts the branch metrics stored in registers BMH 316 and BML 318 to a previously calculated state metric to calculate first and second state metrics. The first and second state metrics are then compared, and the best state metric is saved for the next iteration of state or path metric calculations. The addition or subtraction of BMH 316 is controlled by the state of V₂ and the addition or subtraction of BML 318 is controlled by the state of V₂′. The output of add-compare-select unit 320 is stored in result FIFO 326. Add-compare-select unit 320 stores additional data in registers 328 and 330.

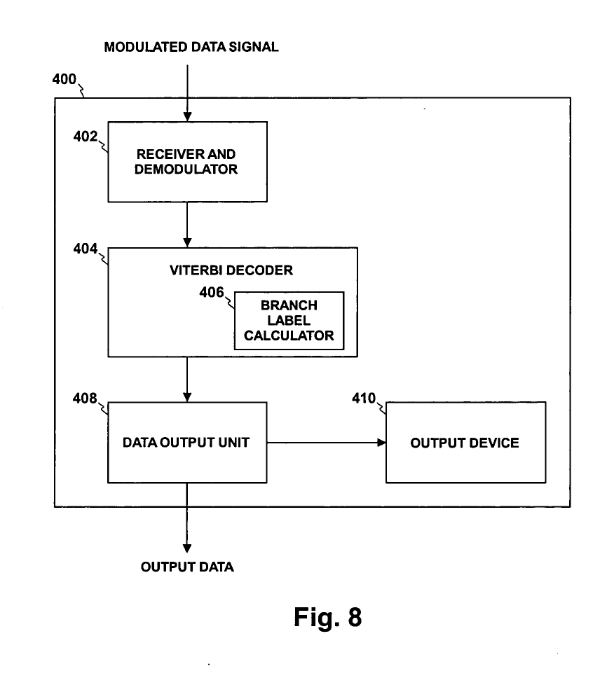

With reference now to FIG. 8, there is depicted a data receiver 400 in accordance with the method and system of the present invention. Data receiver 400 is used for receiving convolutionally encoded data transmitted in the form of a modulated data signal. Data receiver 400 may be implemented with a cell phone, a digital cable receiver, a satellite signal receiver, a wireless networking data receiver such as IEEE 802.11 compliant wireless Ethernet receiver, a cable modem, or the like.

As illustrated, data receiver includes receiver and a demodulator 402, Viterbi decoder 404, data output unit 408, and optionally output device 410. Receiver and demodulator 402 typically receives an analog signal and uses an A to D converter to produce a stream of data bits. Such data bits are encoded with a convolutional encoder similar to encoder 40 shown in FIG. 2. The data bits may be represented as hard or soft decisions.

Viterbi decoder 404 receives data from receiver and demodulator 402 and uses a Viterbi algorithm to decode the data stream. To produce a stream of information bits. In accordance with the present invention, Viterbi decoder 404 includes branch label calculator 406, which may be implemented as shown in FIGS. 5, 6, and 7. Therefore, branch label calculator 406 can compute eight branch labels using a single cycle of a single convolutional encoder. Branch label calculator 406 provides increased Viterbi decoding performance by either reducing the number of circuits or encoders needed calculate eight branch labels using multiple encoders, or by reducing the number of encoder cycles needed to calculate eight branch labels using a single encoder.

Viterbi decoder 404 outputs information bits to data output unit 408. Data output unit 408 formats the information bits or user data and provides the proper electrical and mechanical data interface. For example, data output unit 408 may provide a USB interface, an Ethernet interface, a fire wire interface, or other custom data bus interface.

Output device 410 may be used to provide a human data interface, such as a screen or an audio output. For example, if data receiver 400 is a cellular telephone, output device 410 may be implemented with a screen and an earpiece speaker to provide the user with both audio and video data.

The foregoing description of a preferred embodiment of the invention has been presented for the purpose of illustration and description. It is not intended to be exhaustive or to limit the invention to the precise form disclosed. Obvious modifications or variations are possible in light of the above teachings. The embodiment was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

1. A method in a convolutional decoder for calculating branch labels comprising the steps of:
selecting a group of four consecutive states, Sᵢ, Sᵢ₊₁, Sᵢ₊₂, and Sᵢ₊₃, wherein Sᵢ and Sᵢ₊₁ have next states Sⱼ and Sₖ in a first trellis butterfly and Sᵢ₊₂ and Sᵢ₊₃ have next states Sⱼ₊₁ and Sₖ₊₁ in a second trellis butterfly;
loading state Sᵢ₊₃ into a convolutional encoder and setting the convolutional encoder input bit to 1, wherein the convolutional encoder parameters include a constraint length K and generator polynomials Gₚ[K-2:0], wherein p is an index from 0 to p-1 for p-number of generator polynomials used to produce p-number of encoder output bits [Vₚ₋₁:V₀] and bit G[0] represents a modulo-2 adder connection to the newest bit in an encoder shift register in the convolutional encoder; and
computing a first branch label BL[Vₚ₋₁′:V₀′] for the input equals 1 transition from state Sᵢ₊₁ to state Sₖ in the first trellis butterfly using the formula
Vₚ′=Gₚ[K-3] xor Vₚ
where Gₚ[K-3] is the K-3 bit of the pth generator polynomial and Vₚ is the p^{th} bit of the state Sᵢ₊₃ encoder output bits [Vₚ₋₁:V₀].

2. The method in a convolutional decoder according to claim 1 further comprising the steps of:
determining that the convolutional encoder is configured as a recursive convolutional encoder having a feedback polynomial GF[K-2:0];
in response to determining that the convolutional encoder is configured as a recursive convolutional encoder, computing the first branch label BL[Vₚ₋₁′:V₀′] for the input equals 1 transition from state Sᵢ₊₁ to state Sₖ using the formula
Vₚ′=Gₚ[K-3] xor GF[K-3] xor Vₚ
where Gₚ[K-3] is the K-3 bit of the pth generator polynomial, GF[K-3] is the K-3 bit of the feedback polynomial, and Vₚ is the p^{th} bit of the state Sᵢ₊₃ encoder output bits [Vₚ₋₁:V₀].

3. The method in a convolutional decoder according to claim 1 further comprising the steps of:
computing a branch label by setting a branch label for a transition from state Sᵢ₊₃ to state Sₖ₊₁ equal to encoder output bits [Vₚ₋₁:V₀];
computing a branch label by setting a branch label for a transition from state Sᵢ₊₂ to state Sⱼ₊₁ equal to the branch label for the transition from state Sᵢ₊₃ to state Sₖ₊₁; and
computing branch labels by setting branch labels for transitions from state Sᵢ₊₂ to state Sₖ₊₁ and from state Sᵢ₊₃ to state Sⱼ₊₁ equal to the inverse of the branch label for the transition from state Sᵢ₊₃ to state Sₖ₊₁.

4. The method in a convolutional decoder according to claim 1 further comprising the steps of:
computing a branch label by setting a branch label for a transition from state Sᵢ to state Sⱼ equal to BL[Vₚ₋₁′:V₀′]; and
computing branch labels by setting branch labels for transitions from state Sᵢ to state Sₖ and from state Sᵢ₊₁ to state Sⱼ equal to the inverse of BL[Vₚ₋₁′:V₀′].

5. The method in a convolutional decoder according to claim 1 wherein state indices j and k associated with states Sⱼ and Sₖ, respectively, are related by the formula
k=j+2^{((K-2)-}1)

6. The method in a convolutional decoder according to claim 1 further including the steps of:
addressing a branch metric register file using two least significant bits of a branch label for the input equals 1 transition from state Sᵢ₊₁ to state Sₖ; and
addressing the branch metric register file using two least significant bits of a branch label for the input equals 1 transition from state Sᵢ₊₃ to state Sₖ₊₁.

7. A branch metric unit for a Viterbi decoder comprising:
a state counter for selecting a group of four consecutive states, Sᵢ, Sᵢ₊₁, Sᵢ₊₂, and Sᵢ₊₃, wherein Sᵢ and Sᵢ₊₁ have next states Sⱼ and Sₖ in a first trellis butterfly and Sᵢ₊₂ and Sᵢ₊₃ have next states Sⱼ₊₁ and Sₖ₊₁ in a second trellis butterfly;
a convolutional encoder loaded with state Sᵢ₊₃ and having a convolutional encoder input bit equal to 1, wherein the B convolutional encoder parameters include a constraint length K and generator polynomials Gₚ[K-2:0], wherein p is an index from 0 to p-1 for p-number of generator polynomials used to produce p-number of encoder output bits [Vₚ₋₁:V₀] and bit G[0] represents a modulo-2 adder connection to the newest bit in an encoder shift register in the convolutional encoder; and
a branch label calculator for computing a first branch label BL[Vₚ₋₁′:V₀′] for the input equals 1 transition from state Sᵢ₊₁ to state Sₖ in the first trellis butterfly using the formula
Vₚ′=Gₚ[K-3] xor Vₚ
where Gₚ[K-3] is the K-3 bit of the p^{th} generator polynomial and Vₚ is the p^{th} bit of the state Sᵢ₊₃ encoder output bits [Vₚ₋₁:V₀].

8. The branch metric unit according to claim 7 further comprising:
a mode detector for determining that the convolutional encoder is configured as a recursive convolutional encoder having a feedback polynomial GF[K-2:0];
a branch label calculator responsive to the mode detector for computing the first branch label BL[Vₚ₋₁′:V₀′] for the input equals 1 transition from state Sᵢ₊₁ to state S_{k,} when the convolutional encoder is configured as a recursive convolutional encoder, using the formula
Vₚ′=Gₚ[K-3] xor GF[K-3] xor Vₚ
where Gₚ[K-3] is the K-3 bit of the p^{th} generator polynomial, GF[K-3] is the K-3 bit of the feedback polynomial, and Vₚ is the p^{th} bit of the state Sᵢ₊₃ encoder output bits [Vₚ₋₁:V₀].

9. The branch metric unit according to claim 7 wherein state indices j and k associated with states Sⱼ and Sₖ, respectively, are related by the formula
k=j+2^{((K-2)-1)}.

10. A data receiver for receiving convolutionally encoded data comprising:
a receiver and demodulator for receiving user data;
a Viterbi decoder coupled to the receiver and demodulator, wherein the Viterbi decoder includes a branch metric calculator that includes:
a state counter for selecting a group of four consecutive states, Sᵢ, Sᵢ₊₁, Sᵢ₊₂, and Sᵢ₊₃, wherein Sᵢ and Sᵢ₊₁ have next states Sⱼ and Sₖ in a first trellis butterfly and Sᵢ₊₂ and Sᵢ₊₃ have next states Sⱼ₊₁ and Sₖ₊₁ in a second trellis butterfly;
a convolutional encoder loaded with state Sᵢ₊₃ and having a convolutional encoder input bit equal to 1, wherein the convolutional encoder parameters include a constraint length K and generator polynomials Gₚ[K-2:0], wherein p is an index from 0 to p-1 for p-number of generator polynomials used to produce p-number of encoder output bits [Vₚ₋₁:V₀] and bit G[0] represents a modulo-2 adder connection to the newest bit in an encoder shift register in the convolutional encoder; and
a branch label calculator for computing a first branch label BL[Vₚ₋₁′:V₀′] for the input equals 1 transition from state Sᵢ₊₁ to state Sₖ in the first trellis butterfly using the formula
Vₚ′=Gₚ[K-3] xor Vₚ
where Gₚ[K-3] is the K-3 bit of the p^{th} generator polynomial and Vₚ is the p^{th} bit of the state Sᵢ₊₃ encoder output bits [Vₚ₋₁:V₀]; and
a data output unit coupled to the Viterbi decoder for formatting and outputting the user data.

11. The data receiver according to claim 10 wherein the branch metric calculator in the Viterbi decoder further includes:
a mode detector for determining that the convolutional encoder is configured as a recursive convolutional encoder having a feedback polynomial GF[K-2:0];
a branch label calculator responsive to the mode detector for computing the first branch label BL[Vₚ₋₁′:V₀′] for the input equals 1 transition from state Sᵢ₊₁ to state S_{k,} when the convolutional encoder is configured as a recursive convolutional encoder, using the formula
Vₚ′=Gₚ[K-3] xor GF[K-3] xor Vₚ
where Gₚ[K-3] is the K-3 bit of the p^{th}generator polynomial, GF[K-3] is the K-3 bit of the feedback polynomial, and Vₚ is the p^{th} bit of the state Sᵢ₊₃ encoder output bits [Vₚ₋₁:V₀].

12. The data receiver according to claim 10 further including an output device coupled to the data output unit for outputting an audible signal.

13. The data receiver according to claim 10 wherein the data receiver is a cellular telephone.
